(19) United States
(12) Patent Application Publication
(10) Pub. No.: US 2017/0194523 A1
(43) Pub. Date: Jul. 6, 2017

(54) Photovoltaic With Improved Visibility and Method for Manufacturing Thereof

(71) Applicant: Jusung Engineering Co., Ltd., Gwangju-si (KR)

(72) Inventors: Yong Hyun KIM, Gwangju-si (KR); Chang Kyun PARK, Gwangju-si (KR); Seung-Cheol PYUN, Gwangju-si (KR); Yong Kyu HONG, Gwangju-si (KR)

(73) Assignee: Jusung Engineering Co., Ltd., Gwangju-si (KR)

(21) Appl. No.: 15/117,113

(22) PCT Filed: Jan. 7, 2015
(86) PCT No.: PCT/KR2015/000152

§ 371 Date: Aug. 5, 2016

(30) Foreign Application Priority Data
Feb. 6, 2014 (KR) 10-2014-0013802

(51) Int. Cl. H01L 31/0468; H02S 20/22; H01L 31/0216; H02S 40/42; H01L 31/0224; H01L 31/05

(52) U.S. Cl. CPC H01L 31/0468; H01L 31/022475; H01L 31/0512; H01L 31/02168; H01L 31/022483; H02S 40/42; H02S 20/22

(57) ABSTRACT

Disclosed are a photovoltaic with improved visibility, which can improve optical-to-electric conversion efficiency and can be applied to a window of a building or a view window of a moving means such as a vehicle, and a method of manufacturing the same. The photovoltaic includes a transparent substrate, a transparent electrode formed on one surface of the transparent substrate, a plurality of photovoltaic cells configured to each include a first electrode formed on the transparent electrode, an optical-to-electric conversion part formed on the first electrode, and a second electrode formed on the optical-to-electric conversion part, and a separation part provided between adjacent photovoltaic cells. The separation part exposes the transparent electrode to incident sunlight.

### TECHNICAL FIELD

The present invention relates to a thin-film photovoltaic, and more particularly, to a photovoltaic with improved visibility, which can be applied to a window of a building or a view window of a moving means such as a vehicle, and a method of manufacturing the same.

### BACKGROUND ART

Photovoltaics are apparatuses that convert light energy into electrical energy by using the properties of a semiconductor. That is, the photovoltaics have a P-N junction structure in which a positive (P)-type semiconductor is joined to a negative (N)-type semiconductor. The photovoltaics produce power with the following principle. When sunlight is incident on a photovoltaic having the P-N junction structure, a hole (+) and an electron (−) are generated in a semiconductor by energy of the incident sunlight. At this time, due to an electric field which is generated based on P-N junction, the hole (+) moves toward a P-type semiconductor, and the electron (−) moves toward an N-type semiconductor. Thus, an electric potential is generated, thereby producing power.

The photovoltaics are categorized into substrate-type photovoltaics and thin-film photovoltaics. The substrate-type photovoltaics are manufactured by using a semiconductor material itself, such as silicon, as a substrate, and the thin-film photovoltaics are manufactured by forming a semiconductor in a thin film type on a substrate such as glass.

The substrate-type photovoltaics have slightly better efficiency than the thin-film photovoltaics. However, the substrate-type photovoltaics have a limitation in minimizing a thickness in a process, and since the substrate-type photovoltaics use a high-priced semiconductor substrate, the manufacturing cost increases. On the other hand, the thin-film photovoltaics have slightly lower efficiency than the substrate-type photovoltaics. However, since the thin-film photovoltaics can be manufactured to a thin thickness and can use a low-priced material, the manufacturing cost is reduced, and thus, the thin-film photovoltaics are suitable for mass production.

Recently, as an optical-to-electric conversion efficiency of photovoltaics is improved, window-substituting photovoltaics which are usable in substitution for windows (for example, house windows, building windows, and side windows, rear windows, and sunroofs of vehicles) of buildings or vehicles (a moving means) are being developed. The window-substituting photovoltaics produce power with incident sunlight, and transmit sunlight, which is not used to produce the power, to the inside of a building.

FIG. 1 is a diagram schematically illustrating a related art window-substituting photovoltaic.

Referring to FIG. 1, the related art window-substituting photovoltaic includes a photovoltaic 10 which is attached to a window 1 of a building or a vehicle (a moving means).

The photovoltaic 10 includes a transparent substrate 11, a plurality of photovoltaic cells 12, a light transmitting part 14, and a protective substrate 21.

Each of the plurality of photovoltaic cells 12 includes a rear electrode 12a formed on the transparent substrate 11, an optical-to-electric conversion layer 12b formed on the rear electrode 12a, and a front electrode 12c formed on the optical-to-electric conversion layer 12b. The rear electrode 12a is formed of a metal material on the transparent substrate 11. The optical-to-electric conversion layer 12b is formed on the rear electrode 12a to have a P-N junction structure in which a P-type semiconductor is joined to an N-type semiconductor, and produces power with sunlight which is incident through the front electrode 12d. The front electrode 12c is formed of a transparent material on the optical-to-electric conversion layer 12b. In each of the plurality of photovoltaic cells 12, the optical-to-electric conversion layer 12b formed on the rear electrode 12a is electrically, serially connected to a partial region of the front electrode 12c by a cell separation part which is removed in a direction parallel to a first direction of the transparent substrate 11.

The light transmitting part 14 is formed between the plurality of photovoltaic cells 12 in parallel with a second direction intersecting the first direction of the transparent substrate 11. The light transmitting part 14 is formed by all removing the rear electrode 12a formed on the transparent substrate 11, the optical-to-electric conversion layer 12b, and a partial region of the front electrode 12c, and thus allows incident sunlight to be transmitted to the inside.

The protective substrate 21 is formed to cover the light transmitting part 14 and the plurality of photovoltaic cells 12 formed on the transparent substrate 11, and protects the plurality of photovoltaic cells 12. An outer surface of the protective substrate 21 is attached to the window 1 of a building.

The related art window-substituting photovoltaic produces power with incident sunlight, and enables a user to view the outside from the inside through the light transmitting part 14.

However, in the related art window-substituting photovoltaic, when viewing the outside from the inside, visibility cannot be secured due to reflection light RL caused by a surface reflection of the rear electrode 12a formed of a metal material.

Moreover, in the related art window-substituting photovoltaic, the rear electrode 12a which is formed in a region corresponding to the light transmitting part 14 is removed (or opened) for securing visibility, and for this reason, optical-to-electric conversion efficiency is low.

### DISCLOSURE

### Technical Problem

Accordingly, the present invention is directed to provide a photovoltaic with improved visibility and a method of manufacturing the same that substantially obviate one or more problems due to limitations and disadvantages of the related art.

An aspect of the present invention is directed to provide a photovoltaic with improved visibility, which can improve optical-to-electric conversion efficiency and can be applied to a window of a building or a view window of a moving means such as a vehicle, and a method of manufacturing the same.

In addition to the aforesaid objects of the present invention, other features and advantages of the present invention will be described below, but will be clearly understood by those skilled in the art from descriptions below.

### Technical Solution

To achieve these and other advantages and in accordance with the purpose of the invention, as embodied and broadly described herein, there is provided a photovoltaic with improved visibility including: a transparent substrate; a transparent electrode formed on one surface of the transparent substrate; a plurality of photovoltaic cells configured to each include a first electrode formed on the transparent electrode, an optical-to-electric conversion part formed on the first electrode, and a second electrode formed on the optical-to-electric conversion part; and a separation part provided between adjacent photovoltaic cells, wherein, the separation part exposes the transparent electrode to incident sunlight. Here, the separation part transmits the incident sunlight to the transparent substrate through the transparent electrode.

In another aspect of the present invention, there is provided a method of manufacturing a photovoltaic with improved visibility including: a process (A) of forming a transparent electrode on one surface of a transparent substrate; a process (B) of forming a plurality of photovoltaic cells on the transparent electrode, wherein each of the plurality of photovoltaic cells includes a first electrode, an optical-to-electric conversion part on the first electrode, and a second electrode on the optical-to-electric conversion part; and a process (C) of forming a separation part between adjacent photovoltaic cells, wherein, the transparent electrode overlapping the separation part is formed to be exposed to incident sunlight. Here, the process (C) includes forming the separation part by removing a certain region of each of the first electrode, the optical-to-electric conversion part, and the second electrode which are formed on the transparent electrode.

### Advantageous Effect

As described above, according to the embodiments of the present invention, since the photovoltaic cells which are adjacent to each other with the light transmitting part (or the separation part) therebetween are connected to the first electrode through the connection layer (or the transparent electrode) which is formed to overlap the light transmitting part, a visibility of the photovoltaic is secured through the light transmitting part, and optical-to-electric conversion efficiency can be improved.

Moreover, according to the embodiments of the present invention, since the anti-reflection layer (or the transparent electrode) is formed between the transparent substrate and the first electrode formed of a metal material, visibility can be prevented from being reduced due to a light reflection of a metal electrode when viewing the outside from the inside.

### DESCRIPTION OF DRAWINGS

FIG. 1 is a diagram schematically illustrating a related art window-substituting photovoltaic;

FIG. 2 is a diagram schematically illustrating a photovoltaic with improved visibility according to an embodiment of the present invention;

FIG. 3 is a cross-sectional view taken along line I-I′ of FIG. 2;

FIG. 4 is a cross-sectional view schematically illustrating a photovoltaic used as a window substitute, according to an embodiment of the present invention; and

FIGS. 5A to 5G are diagrams for describing a method of manufacturing a photovoltaic with improved visibility, according to an embodiment of the present invention.

### MODE FOR INVENTION

The terms described in the specification should be understood as follows. It will be further understood that the terms “comprises”, “comprising,”, “has”, “having”, “includes” and/or “including”, when used herein, specify the presence of stated features, integers, steps, operations, elements, and/or components, but do not preclude the presence or addition of one or more other features, integers, steps, operations, elements, components, and/or groups thereof. The term “at least one” should be understood as including any and all combinations of one or more of the associated listed items. For example, the meaning of “at least one of a first item, a second item, and a third item” denotes the combination of all items proposed from two or more of the first item, the second item, and the third item as well as the first item, the second item, or the third item. The term “on” should be construed as including a case where one element is formed at a top of another element and moreover a case where a third element is disposed therebetween.

Hereinafter, a photovoltaic with improved visibility and a method of manufacturing the same according to an embodiment of the present invention will be described in detail with reference to the accompanying drawings.

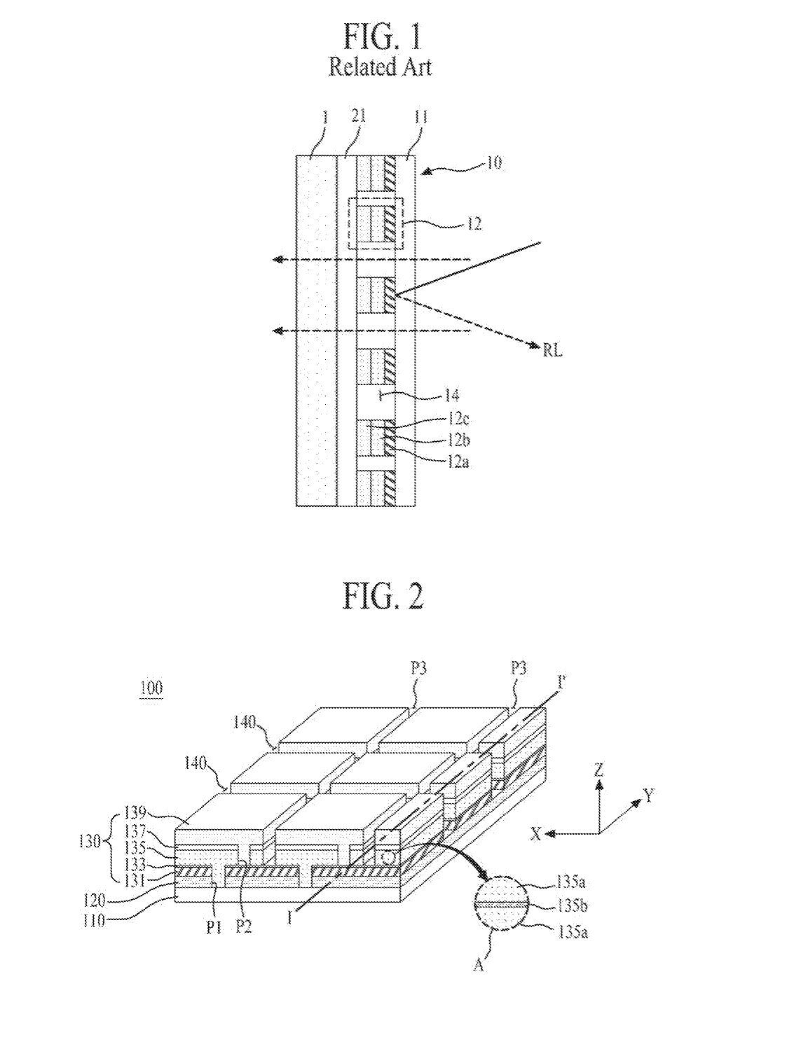

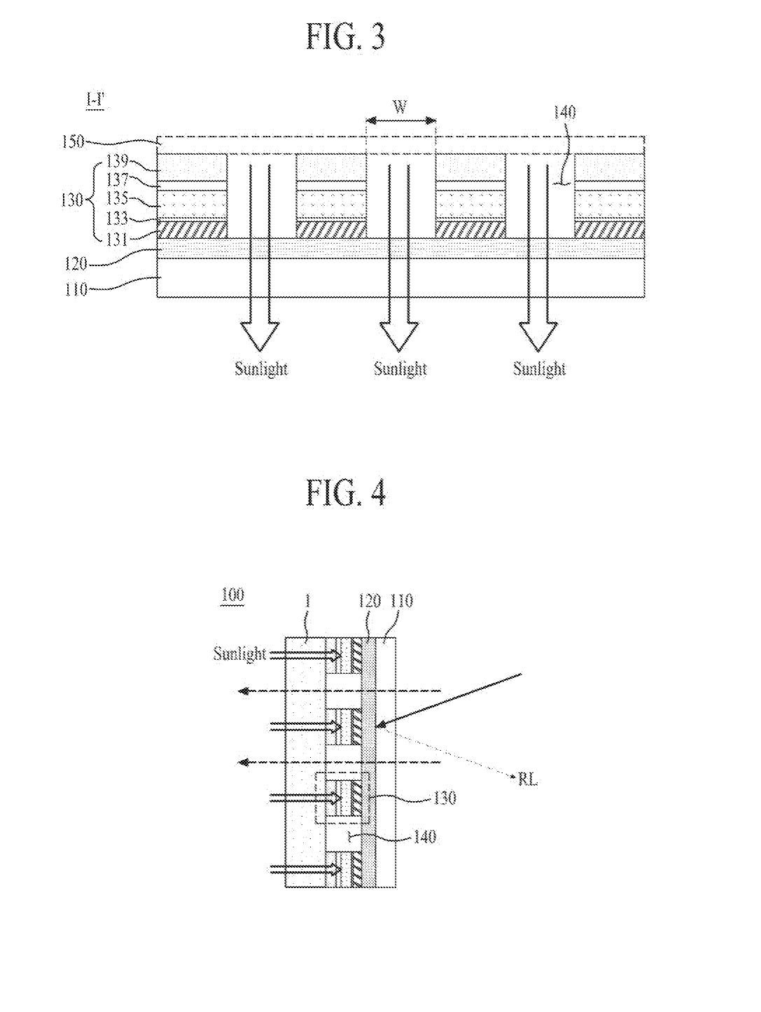

FIG. 2 is a diagram schematically illustrating a photovoltaic 100 with improved visibility according to a first embodiment of the present invention, and FIG. 3 is a cross-sectional view taken along line I-I′ of FIG. 2.

Referring to FIGS. 2 and 3, the photovoltaic 100 with improved visibility according to the first embodiment of the present invention includes a transparent substrate 110, a transparent electrode 120, a plurality of photovoltaic cells 130, and a light transmitting part 140 formed between the plurality of photovoltaic cells 130.

The transparent substrate 110 may be formed of transparent glass, a transparent plastic substrate, or a transparent flexible plastic substrate.

The transparent electrode 120 is formed all over one surface of the transparent substrate 110 to have a certain thickness. The transparent electrode 120 may include one transparent conductive material selected from indium tin oxide (ITO), indium zinc oxide (IZO), ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃. In addition, the transparent electrode 120 may include a fine concave-convex structure which is formed on one surface of the transparent electrode 120.

Each of the photovoltaic cells 130 is formed on the transparent substrate 110, namely, the transparent electrode 120, and includes a first electrode 131, a second electrode 139, and an optical-to-electric conversion part 135 between the first electrode 131 and the second electrode 139. In more detail, each of the plurality of photovoltaic cells 130 may include the first electrode 131, an internal reflective electrode 133, an electrode separation pattern P1, the optical-to-electric conversion part 135, a transparent conductive layer 137, a contact pattern P2, the second electrode 139, and a cell separation pattern P3.

The first electrode 131 is formed all over a top of the transparent electrode 120 to have a certain thickness. The first electrode 131 may be formed of a metal material such as Ag, Al, Cu, Ag+Mo, Ag+Ni, or Ag+Cu. Here, when a fine concave-convex structure is formed on a surface of the transparent electrode 120, a fine concave-convex structure corresponding to the fine concave-convex structure of the transparent electrode 120 may be formed on a surface of the first electrode 131.

The internal reflective electrode 133 is formed on the first electrode 131. In more detail, the internal reflective electrode 133 is formed of a transparent conductive material on the first electrode 131, and reflects light, which travels to the first electrode 131 without being absorbed by the optical-to-electric conversion part 135, to again transfer the light to the optical-to-electric conversion part 135. The internal reflective electrode 133 may be formed of the same material as that of the transparent electrode 120, or may be formed of one material selected from ITO IZO, ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃. Here, when a fine concave-convex structure is formed on a surface of each of the transparent electrode 120 and the first electrode 131, a fine concave-convex structure corresponding to the fine concave-convex structure may be formed on a surface of the internal reflective electrode 133. According to an embodiment of the present invention, the first electrode 131 and the internal reflective electrode 133 are formed in a stacked structure, and thus, a light reflection rate by the first electrode 131 and the internal reflective electrode 133 is 90% or more.

The electrode separation pattern P1 is formed to have a certain interval along a first direction Y (for example, a vertical direction of the transparent substrate 110) of the transparent substrate 110, and separates a plurality of the first electrodes 131 at certain intervals. The electrode separation pattern P1 is formed by removing a certain region of each of the first electrode 131 and the transparent electrode 120 which overlap each other in order for a certain region of the transparent substrate 110 to be exposed.

The optical-to-electric conversion part 135 is formed between the first electrode 131 and the second electrode 139, and includes at least one optical-to-electric conversion layer 135a that produces power with sunlight which is incident through the second electrode 139.

The optical-to-electric conversion layer 135a may be formed of a silicon-based semiconductor material, and may be formed in an NIP structure where an N-type semiconductor layer, an I-type semiconductor layer, and a P-type semiconductor layer are sequentially stacked. When the optical-to-electric conversion layer 135a is formed in the NIP structure, the I-type semiconductor layer is depleted by the P-type semiconductor layer and the N-type semiconductor layer, and thus, an electric field is internally generated. A hole and an electron which are generated by the sunlight are drifted by the electric field, and are collected by the P-type semiconductor layer and the N-type semiconductor layer. Also, when the optical-to-electric conversion layer 135a is formed in the NIP structure, the N-type semiconductor layer may be formed on the first electrode 131, and subsequently, the I-type semiconductor layer and the P-type semiconductor layer may be formed. The reason is for that since a drift mobility of a hole is lower than a drift mobility of an electron, the P-type semiconductor layer is formed close to a light receiving surface so as to maximize collection efficiency by incident light.

In addition, when the optical-to-electric conversion part 135 includes the optical-to-electric conversion layer 135a having a multi-layer structure, as illustrated in an enlarged portion A of FIG. 2, the optical-to-electric conversion part 135 may further include a buffer layer 135b which is formed between a plurality of the optical-to-electric conversion layers 135a. Here, the buffer layer 135b enables a hole and an electron to smoothly move through tunnel junction between the optical-to-electric conversion layers 135a. The buffer layer 135b may be omitted, but may be formed between the plurality of optical-to-electric conversion layers 135a so as to enhance an efficiency of the photovoltaic 100.

The transparent conductive layer 137 is formed on the optical-to-electric conversion part 135. The transparent conductive layer 137 scatters sunlight, which is incident through the second electrode 139, to travel the sunlight at various angles, and increases a ratio of light which is incident on the optical-to-electric conversion part 135 through the second electrode 139, thereby enhancing an efficiency of the photovoltaic. The transparent conductive layer 137 may be omitted, but may be formed between the optical-to-electric conversion part 135 and the second electrode 139 so as to enhance an efficiency of the photovoltaic 100.

The contact pattern P2 is formed in parallel with the electrode separation pattern P1, and exposes a certain region of a top of the first electrode 131 or the internal reflective electrode 133 adjacent to the electrode separation pattern P1. That is, the contact pattern P2 is formed by removing a certain region of each of the transparent conductive layer 137 and the optical-to-electric conversion part 135 which are formed on the first electrode 131 adjacent to the electrode separation pattern P1.

The second electrode 139 is formed inside the contact pattern P2 and on the transparent conductive layer 137 so as to be electrically connected to the first electrode 131 through the contact pattern P2. The second electrode 139 is formed of a transparent conductive material in order for incident sunlight to be incident on the optical-to-electric conversion part 135. For example, the second electrode 139 may be formed of one material selected from ITO, IZO, ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃, and may be formed of the same material as that of the transparent electrode 120.

The cell separation pattern P3 is formed in parallel with the contact pattern P2, and exposes a certain region of the top of the first electrode 131 or the internal reflective electrode 133 adjacent to the contact pattern P2. That is, the cell separation pattern P3 is formed by removing a certain region of each of the optical-to-electric conversion part 135, the transparent conductive layer 137, and the second electrode 139 which are formed on the first electrode 131. Therefore, the plurality of photovoltaic cells 130 which are electrically separated from each other by the cell separation pattern P3 and are electrically, serially connected to each other through the contact pattern P2 are formed on the transparent substrate 110.

The light transmitting part 140 is provided between adjacent photovoltaic cells 130 to have a certain width W along a second direction X (for example, a horizontal direction of the transparent substrate 110) intersecting the first direction Y of the transparent substrate 110, and acts as a separation part that exposes the transparent electrode 120, which is formed between the photovoltaic cells 130 adjacent to each other in the first direction Y, to incident sunlight, and spatially separates the photovoltaic cells 130 which are formed on the transparent electrode 120 and are adjacent to each other in the first direction Y. The light transmitting part 140 includes only the transparent electrode 120 formed on the transparent substrate 110, and in more detail, is formed by removing a certain region of each of the first electrode 131, the internal reflective electrode 133, the optical-to-electric conversion part 135, the transparent conductive layer 137, and the second electrode 139 except the transparent electrode 120 formed on the transparent substrate 110.

The light transmitting part 140 is formed to intersect the cell separation pattern P3 through the same process as that of the cell separation pattern P3, and thus provides a transmission path of sunlight which is transmitted toward the transparent substrate 110 and increases a light opening rate (or a light transmission rate) of the photovoltaic 100, thereby enhancing a visibility of the photovoltaic 100. Here, the light opening rate of the photovoltaic 100 may be determined based on an area ratio of the light transmitting part 140 to an arear of the transparent substrate 110, and particularly, may be determined based on a width W of the light transmitting part 140 with respect to the transparent substrate 110 having the same size.

The first electrodes 131 of the photovoltaic cells 130 which are adjacent to each other with the light transmitting part 140 therebetween are connected to each other, and thus, the transparent electrode 120 acts as a connection layer that electrically connects the photovoltaic cells 130 which are adjacent to each other with the light transmitting part 140 therebetween.

Moreover, the transparent electrode 120 acts as an anti-reflection layer that prevents light, which is incident from a rear surface of the transparent substrate 110, from being reflected by the first electrode 131. In this case, the transparent electrode 120 is formed to have a surface concave-convex structure or a high surface roughness, and diffusely reflects the light which is incident from the rear surface of the transparent substrate 110, thereby preventing the light from being reflected by the first electrode 131. To this end, the transparent electrode 120 may be formed by a deposition process such as a metal organic chemical vapor deposition (MOCVD) process which forms a concave-convex structure on a surface of a deposition material or forms the surface of the deposition material to have a high surface roughness.

The photovoltaic 100 with improved visibility according to an embodiment of the present invention may further include a transparent cover member 150 which is formed on the second electrode 139 to overlap the transparent substrate 110. That is, the transparent cover member 150 may be formed on the second electrode 139 to cover the plurality of photovoltaic cells 130 and the light transmitting part 140. The transparent cover member 150 may be formed of a window used as a window of a building (or a moving means), the same material as that of the transparent substrate 110, a transparent polymer, or a protective sheet (or a protective layer). The transparent cover member 150 may be omitted depending on a structure of the photovoltaic 100.

On the other hand, a functional film (not shown) may be additionally attached to the other surface of the transparent substrate 110 facing an indoor side, and the functional film may include at least one film selected from a window colored film which gives a color to the transparent substrate 110, a heat blocking film, an ultraviolet (UV) blocking film, and an anti-reflection film. Here, the functional film may include an opening pattern (not shown) overlapping the light transmitting part 140.

The photovoltaic 100 with improved visibility according to an embodiment of the present invention, as illustrated in FIG. 4, is coupled to the window 1 which enables the outside to be viewed from the inside. Here, the window 1 may be a house window, a building window, and a side window, a rear window, or a sunroof of a vehicle. In this case, the second electrode 139 is disposed adjacent to the window 1 to form a light receiving surface. Therefore, some of sunlight passing through the window 1 pass through the second electrode 139, are absorbed by the optical-to-electric conversion part 135, and are converted into electrical energy, and the other sunlight passes through the light transmitting part 140 and the transparent electrode 120 and transparent substrate 110 corresponding thereto and is incident on the inside.

Particularly, according to the present embodiment, since, the photovoltaic cells 130 which are adjacent to each other with the light transmitting part 140 therebetween are connected to each other are connected to the first electrode 131 through the transparent electrode 120 which is formed to overlap the light transmitting part 140, a visibility of the photovoltaic is secured through the light transmitting part 140 including only the transparent electrode 120, and optical-to-electric conversion efficiency can be improved. Moreover, according to the present embodiment, since the transparent electrode 120 is formed between the transparent substrate 110 and the first electrode 131 formed of a metal material, reflection light RL caused by a surface reflection of the first electrode 131 is minimized.

Therefore, the photovoltaic 100 with improved visibility according to an embodiment of the present invention may be sufficiently used in substitution for a window (for example, a house window, a building window, and a side window, a rear window, or a sunroof of a vehicle) of a building or a vehicle (a moving means).

In the above-described photovoltaic 100 with improved visibility according to an embodiment of the present invention, the optical-to-electric conversion part 135 has been described above as being formed of a silicon-based semiconductor material, but is not limited thereto. The optical-to-electric conversion part 135 may be formed of a □-□-□ compound in which CuInGaSe (CIGS) that absorbs incident light to produce power is a representative, a □-□ compound in which cadmium telluride (CdTe) is a representative, or a □-□ compound in which gallium arsenide (GaAs) is a representative.

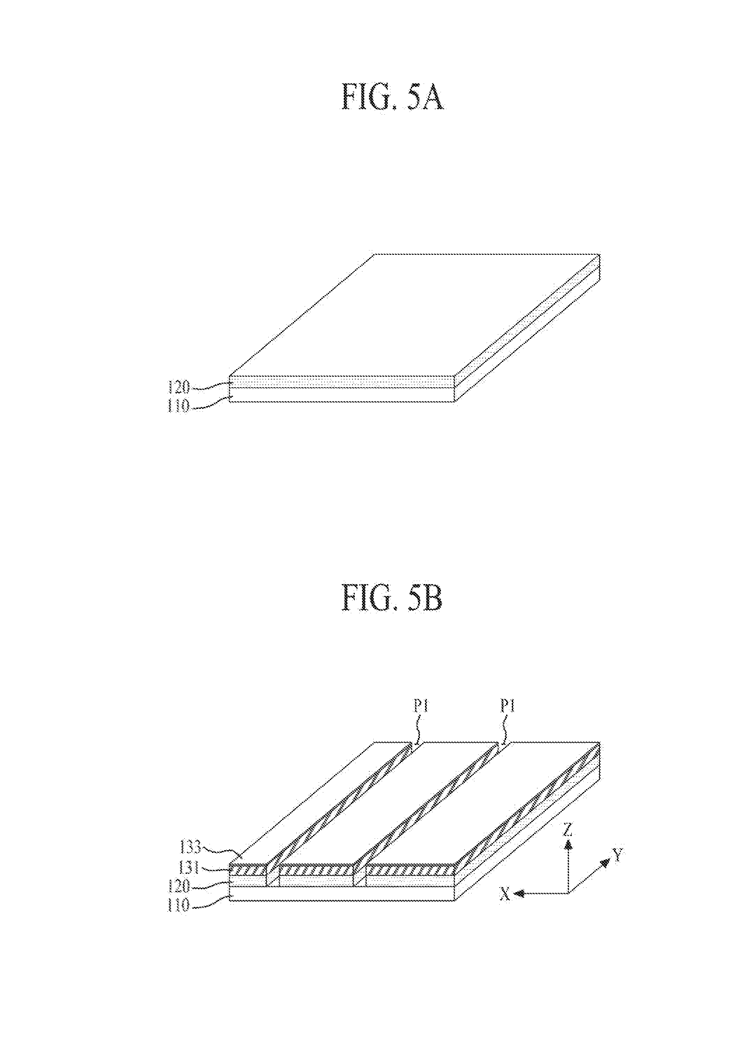

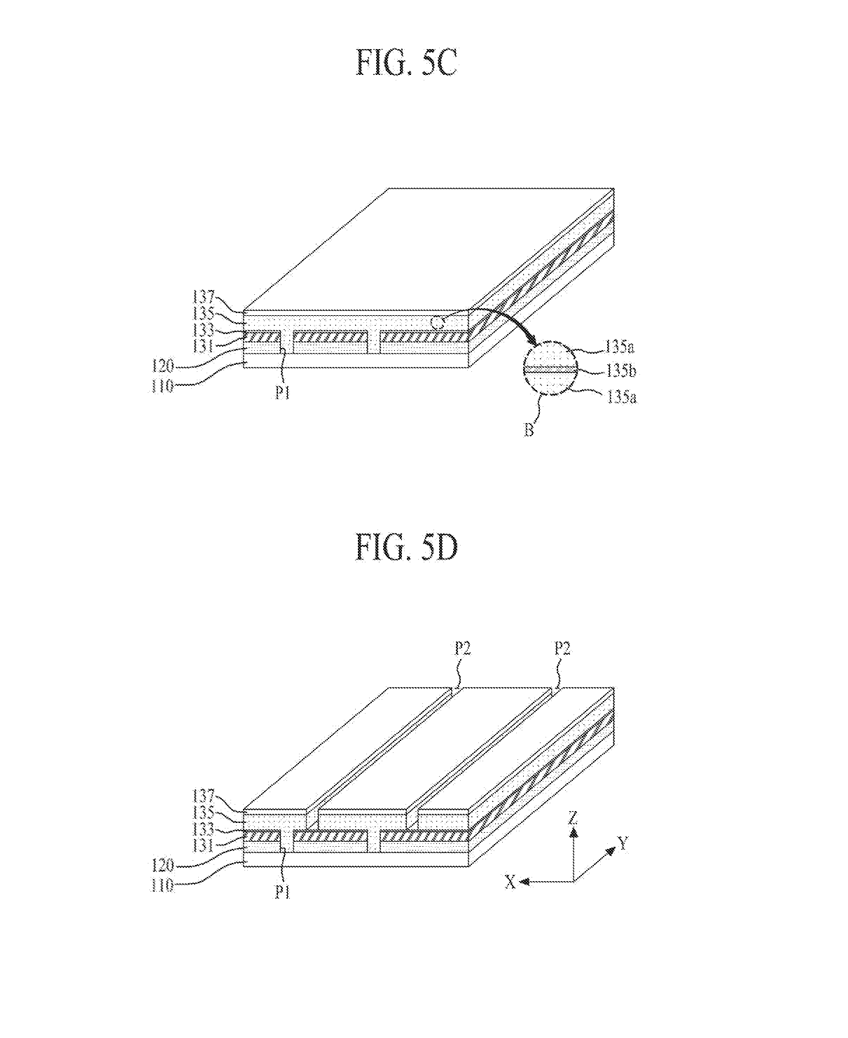

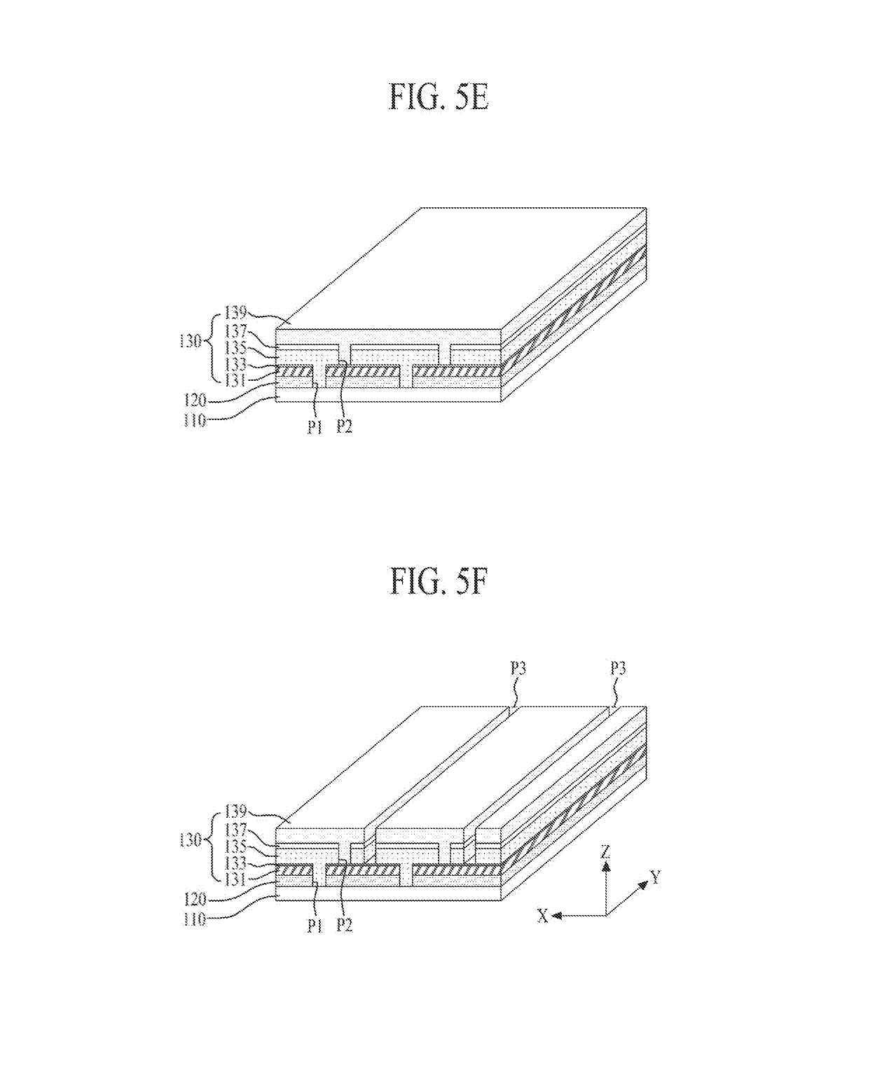

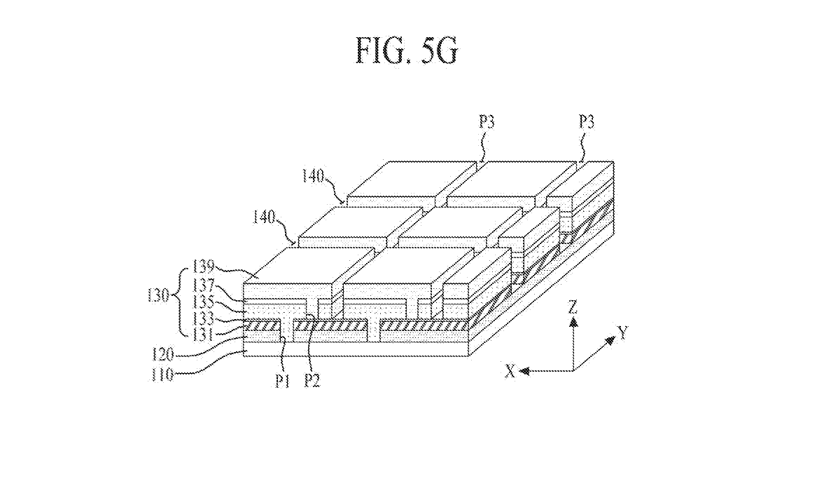

FIGS. 5A to 5G are diagrams for describing a method of manufacturing a photovoltaic with improved visibility, according to an embodiment of the present invention, and illustrate a method of manufacturing the photovoltaic with improved visibility according to an embodiment of the present invention illustrated in FIG. 2. Hereinafter, a description repetitive of a structure of each element is not provided.

First, as illustrated in FIG. 5A, the transparent electrode 120 is formed all over a surface of the transparent substrate 110 to have a certain thickness. The transparent electrode 120 may include one transparent conductive material selected from ITO, IZO, ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃. The transparent electrode 120 may be formed by a sputtering process or the MOCVD process depending on a material.

Optionally, a fine concave-convex structure may be formed on a surface of the transparent electrode 120 through a texturing process. The texturing process is a process which forms the surface of the transparent electrode 120 in a rough concave-convex structure and processes the surface of the transparent electrode 120 in a shape like a surface of fabric. The texturing process may include an etching process using a photolithography, an anisotropic etching process using a chemical solution, or a groove forming process using mechanical scribing.

Subsequently, as illustrated in FIG. 5B, the first electrode 131 is formed all over the transparent electrode 120.

The first electrode 131 may be formed by a one-time printing process using a metal paste which includes Ag, Al, Cu, Ag+Mo, Ag+Ni, or Ag+Cu.

The printing process may include a screen printing process, an inkjet printing process, a gravure printing process, a gravure offset printing process, a reverse printing process, a flexo printing process, or a micro contact printing process. Here, the screen printing process is a process in which an ink is disposed on a screen, and is transferred through a mesh of the screen by moving the ink while pressurizing a squeegee at a certain pressure. The inkjet printing process is a process that performs printing by colliding a very small drop of an ink with a substrate. The gravure printing process is a process that removes an ink gotten on a flat non-printing part by using a doctor blade, and transfers only an ink gotten on a printing part which is recessed by etching, thereby performing printing. The gravure offset printing process is a process that transfers an ink from a printing plate to a blanket, and again transfers the ink of the blanket to a substrate. The reverse printing process is a process that performs printing by using a solvent as an ink. The flexo printing process is a process that performs printing by coating an embossed portion with an ink. The micro contact printing process is a process in which a desired material is placed on a stamp, and printing is performed by imprinting the material like a seal.

The first electrode 131 is printed by the above-described printing process, and then, a firing process of firing the printed first electrode 131 is additionally performed.

The first electrode 131 may be formed by a sputtering process. In this case, when the first electrode 131 is formed by the printing process, the cost of materials increases compared to the sputtering process, and an optical-to-electric conversion efficiency of the photovoltaic is relatively low. However, since a surface roughness of the first electrode 131 is high, a reflection rate by diffuse reflection is reduced, and thus, a visibility of the photovoltaic is easily secured. Accordingly, in terms of visibility, the first electrode 131 may be formed by the printing process.

Subsequently, the internal reflective electrode 133 is formed on the first electrode 131 to have a thinner thickness than that of the first electrode 131. The internal reflective electrode 133 may be formed of the same material as that of the transparent electrode 120, or may be formed of a transparent conductive material including at least one material selected from ITO, IZO, ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃. A process of forming the internal reflective electrode 133 may be omitted, but as described above, may not be omitted for increasing a reflection rate of the first electrode 131. In the following description, it is assumed that the internal reflective electrode 133 is formed.

Subsequently, the electrode separation pattern P1 is formed to have a certain interval along the first direction Y (for example, the vertical direction of the transparent substrate 110) of the transparent substrate 110, and the plurality of first electrodes 131 are separated from each other at certain intervals. For example, the electrode separation pattern P1 may be formed by a laser scribing process that removes a certain region of each of the internal reflective electrode 133, the first electrode 131, and the transparent electrode 120 which overlap each other.

Subsequently, as illustrated in FIG. 5C, the optical-to-electric conversion part 135 which includes the internal reflective electrode 133 and the electrode separation pattern P1 is formed on the optical-to-electric conversion part 135, and then, the transparent conductive layer 137 is formed on the optical-to-electric conversion part 135. Here, the transparent conductive layer 137 may not be formed. However, in the following description, it is assumed that the transparent conductive layer 137 is formed.

The optical-to-electric conversion part 135 according to an embodiment of the present invention may be formed as the single-layer optical-to-electric conversion layer 135a having the NIP structure where the N-type semiconductor layer, the I-type semiconductor layer, and the P-type semiconductor layer are sequentially stacked. Here, instead of the I-type semiconductor layer, an N-type or P-type semiconductor layer having a thinner thickness than that of the N-type or P-type semiconductor layer may be formed, and instead of the I-type semiconductor layer, an N-type or P-type semiconductor layer having a doping concentration lower than that of the N-type or P-type semiconductor layer may be formed.

An optical-to-electric conversion part 135 according to another embodiment, as illustrated in an enlarged portion B of FIG. 5C, may be formed in a tandem structure where a first optical-to-electric conversion layer 135a having the NIP structure, a buffer layer 135b, and a second optical-to-electric conversion layer 135c having the NIP structure are sequentially stacked, but is not limited thereto. The optical-to-electric conversion part 135 may include two or more the optical-to-electric conversion layers 135a and the buffer layer 135b between the two or more optical-to-electric conversion layers 135a. Here, the buffer layer 135b may be formed of a transparent conductive material.

Subsequently, as illustrated in FIG. 5D, the contact pattern P2 is formed by removing a certain region of each of the transparent conductive layer 137 and the optical-to-electric conversion part 135, which are formed on the internal reflective electrode 133, so as to expose a certain region of the internal reflective electrode 133 which is parallel to and adjacent to the electrode separation pattern P1. Here, the contact pattern P2 may be formed by the laser scribing process.

Optionally, the contact pattern P2 may be formed by removing a certain region of each of the internal reflective electrode 133, the optical-to-electric conversion part 135, and the transparent conductive layer 137, which are formed on the first electrode 131, so as to expose a certain region of the first electrode 131 adjacent to the electrode separation pattern P1.

Subsequently, as illustrated in FIG. 5E, the second electrode 139 having a certain thickness is formed on the contact pattern P2 and the transparent conductive layer 137. Here, the second electrode 139 may be formed of a transparent conductive material including at least one material selected from ITO, IZO, ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃. The second electrode 139 may be formed by a deposition process such as the sputtering process or the MOCVD process depending on a material.

Subsequently, as illustrated in FIG. 5F, the cell separation pattern P3 is formed by removing a certain region of each of the optical-to-electric conversion part 135, the transparent conductive layer 137, and the second electrode 139, which are formed on the internal reflective electrode 133, so as to expose a certain region of the internal reflective electrode 133 adjacent to the contact pattern P2. Therefore, the plurality of photovoltaic cells 130 which are electrically separated from each other by the cell separation pattern P3 and are electrically, serially connected to each other through the contact pattern P2 are formed on the transparent substrate 110.

The cell separation pattern P3 may be formed by the laser scribing process or an etching process using a mask.

Optionally, the cell separation pattern P3 may be formed by removing a certain region of each of the internal reflective electrode 133, the optical-to-electric conversion part 135, the transparent conductive layer 137, and the second electrode 139, which are formed on the first electrode 131, so as to expose a certain region of the first electrode 131 adjacent to the contact pattern P2.

Subsequently, as illustrated in FIG. 5G, the light transmitting part 140 which has a certain width and a certain interval along the second direction X of the transparent substrate 110 to intersect the cell separation pattern P3 and exposes a certain region of the transparent electrode 120 is formed.

In more detail, the light transmitting part 140 is formed by removing a certain region of each of the first electrode 131, the internal reflective electrode 133, the optical-to-electric conversion part 135, the transparent conductive layer 137, and the second electrode 139 except the transparent electrode 120 formed on the transparent substrate 110. Therefore, the plurality of photovoltaic cells 130 which are spatially separated from each other by the light transmitting part 140 (or the separation part) is formed in the first direction Y of the transparent substrate 110, and the first electrodes 131 of the photovoltaic cells 130 which are adjacent to each other with the light transmitting part 140 therebetween are connected to each other through the transparent electrode 120 (or the connection layer).

A width and an interval of the light transmitting part 140 may be determined based on a light opening rate of the photovoltaic to an area of the transparent substrate 110. The light transmitting part 140 may be formed by the laser scribing process or the etching process using the mask.

Optionally, the cell separation pattern P3 may be formed in the same structure as that of the light transmitting part 140. In this case, the cell separation pattern P3 may be formed by removing a certain region of each of the first electrode 131, the internal reflective electrode 133, the optical-to-electric conversion part 135, the transparent conductive layer 137, and the second electrode 139, which are formed on the transparent electrode 120, so as to expose a certain region of the transparent electrode 120 adjacent to the contact pattern P2. In this case, the cell separation pattern P3 and the light transmitting part 140 may be simultaneously formed by the etching process using the mask, or may be successively formed by the laser scribing process.

The window 1 (see FIG. 4) is coupled to the second electrode 139 to cover the plurality of photovoltaic cells 130 and the light transmitting part 140 by using a transparent adhesive member such as a transparent adhesive sheet or a transparent adhesive, and thus finishes a photovoltaic module which is usable in substation for a window (for example, a house window, a building window, and a side window, a rear window, or a sunroof of a vehicle) of a building or a vehicle (a moving means).

As another example, a photovoltaic is finished by forming the transparent cover member 150 (see FIG. 3) on the second electrode 130 so as to cover the plurality of photovoltaic cells 130 and the light transmitting part 140. In this case, the transparent cover member 150 may be formed of the same material as that of the transparent substrate 110, a transparent polymer, or a protective sheet. The photovoltaic including the transparent cover member 150 is coupled to a window, which is used as a window of a building or a vehicle (a moving means), by a transparent adhesive member such as a transparent adhesive sheet or a transparent adhesive and thus is installed in substation for a window (for example, a house window, a building window, and a side window, a rear window, or a sunroof of a vehicle) of a vehicle.

In the above-described method of manufacturing the photovoltaic, the optical-to-electric conversion part 135 has been described above as being formed of a silicon-based semiconductor material, but is not limited thereto. The optical-to-electric conversion part 135 may be formed of a □-□-□ compound in which CuInGaSe (CIGS) is a representative, a □-□ compound in which cadmium telluride (CdTe) is a representative, or a □-□ compound in which gallium arsenide (GaAs) is a representative.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

1. A photovoltaic with improved visibility, the photovoltaic comprising:
a transparent substrate;
a transparent electrode formed on one surface of the transparent substrate;
a plurality of photovoltaic cells configured to each include a first electrode formed on the transparent electrode, an optical-to-electric conversion part formed on the first electrode, and a second electrode formed on the optical-to-electric conversion part; and
a separation part provided between adjacent photovoltaic cells,
wherein the separation part exposes the transparent electrode to incident sunlight.

2. The photovoltaic of claim 1, wherein, the separation part transmits the incident sunlight to the transparent substrate through the transparent electrode.

3. A photovoltaic with improved visibility, the photovoltaic comprising:
a transparent substrate;
a plurality of photovoltaic cells configured to each include a first electrode formed on one surface of the transparent substrate, an optical-to-electric conversion part formed on the first electrode, and a second electrode formed on the optical-to-electric conversion part;
a light transmitting part provided between adjacent photovoltaic cells; and
a connection layer configured to electrically connect first electrodes of photovoltaic cells which are adjacent to each other with the light transmitting part therebetween.

4. The photovoltaic of claim 3, wherein, the connection layer is a transparent electrode that is formed on the one surface of the transparent substrate to overlap the first electrode of each of the plurality of photovoltaic cells and the light transmitting part.

5. The photovoltaic of claim 4, wherein, the light transmitting part transmits the incident sunlight to the transparent substrate through the transparent electrode.

6. A photovoltaic with improved visibility, the photovoltaic comprising:
a transparent substrate;
a plurality of photovoltaic cells configured to each include a first electrode formed on one surface of the transparent substrate, an optical-to-electric conversion part formed on the first electrode, and a second electrode formed on the optical-to-electric conversion part;
a light transmitting part provided between adjacent photovoltaic cells; and
an anti-reflection layer formed to overlap the first electrode of each of the plurality of photovoltaic cells and the light transmitting part and configured to prevent light, which is incident from the other surface of the transparent substrate onto the first electrode, from being reflected and transmit sunlight, which is incident on the light transmitting part, to the transparent substrate.

7. The photovoltaic of claim 6, wherein, the anti-reflection layer is a transparent electrode that is formed between the transparent substrate and the first electrode of each of the plurality of photovoltaic cells and is formed on the one surface of the transparent substrate overlapping the light transmitting part.

8. The photovoltaic of claim 1, wherein the transparent electrode comprises one material selected from indium tin oxide (ITO), indium zinc oxide (IZO), ZnO, ZnO:B, ZnO:Al, ZnO:Ga, SnO₂, SnO₂:F, SnO₂:B, SnO₂:Al, In₂O₃, Ga₂O₃—In₂O₃, and ZnO—In₂O₃.

9. The photovoltaic of claim 1, wherein the first electrode comprises one material selected from Ag, Al, Cu, Ag+Mo, Ag+Ni, and Ag+Cu.

10. The photovoltaic of claim 1, wherein
the optical-to-electric conversion part comprises at least one optical-to-electric conversion layer formed between the first electrode and the second electrode, and
the at least one optical-to-electric conversion layer comprises an N-type semiconductor layer, an I-type semiconductor layer, and a P-type semiconductor layer which are sequentially formed on the first electrode.

11. The photovoltaic of claim 1, wherein
the optical-to-electric conversion part comprises at least one optical-to-electric conversion layer formed between the first electrode and the second electrode, and
the at least one optical-to-electric conversion layer comprises one selected from a I-III-VI compound, a II-VI compound, and a III-V compound.

12. The photovoltaic of claim 1, further comprising a transparent cover member formed on the second electrode to overlap the transparent substrate.

13. The photovoltaic of claim 12, wherein, the transparent cover member is a window that is used as a window of a building or a moving means.

14. The photovoltaic of claim 1, further comprising a functional film formed on the other surface of the transparent substrate,
wherein the functional film comprises at least one film selected from a heat blocking film, an ultraviolet (UV) blocking film, an anti-reflection film, and a window colored film which gives a color to the transparent substrate.

15-27. (canceled)

28. The photovoltaic of claim 3, wherein the optical-to-electric conversion part comprises at least one optical-to-electric conversion layer formed between the first electrode and the second electrode.

29. The photovoltaic of claim 6, wherein the optical-to-electric conversion part comprises at least one optical-to-electric conversion layer formed between the first electrode and the second electrode.

30. The photovoltaic of claim 3, further comprising a transparent cover member formed on the second electrode to overlap the transparent substrate.

31. The photovoltaic of claim 3, further comprising a functional film formed on the other surface of the transparent substrate,
wherein the functional film comprises at least one film selected from a heat blocking film, an ultraviolet (UV) blocking film, an anti-reflection film, and a window colored film which gives a color to the transparent substrate.

32. The photovoltaic of claim 6, further comprising a transparent cover member formed on the second electrode to overlap the transparent substrate.

33. The photovoltaic of claim 6, further comprising a functional film formed on the other surface of the transparent substrate,
wherein the functional film comprises at least one film selected from a heat blocking film, an ultraviolet (UV) blocking film, an anti-reflection film, and a window colored film which gives a color to the transparent substrate.
